(19) United States
(12) Patent Application Publication
(10) Pub. No.: US 2025/0259878 A1
(43) Pub. Date: Aug. 14, 2025

(54) LIFT PIN ASSEMBLY FOR A SUSCEPTOR OF A PROCESSING CHAMBER

(71) Applicant: Applied Materials, Inc., Santa Clara, CA (US)

(72) Inventors: Chen-Yao CHAO, Santa Clara, CA (US); Seng Hoe TAN, Singapore (SG); Keyan Zang, Singapore (SG); Kazuyoshi KOBASHI, Santa Clara, CA (US); Ryan Sungbin HU, Santa Clara, CA (US); Kuan Chien SHEN, Sunnyvale, CA (US); Masato ISHII, Sunnyvale, CA (US)

(21) Appl. No.: 19/028,881

(22) Filed: Jan. 17, 2025

Related U.S. Application Data
(60) Provisional application No. 63/553,565, filed on Feb. 14, 2024.

(51) Int. Cl. H01L 21/687

(52) U.S. Cl. CPC H01L 21/68742; H01L 21/68757

(57) ABSTRACT

Disclosed herewith are a lift pin assembly, a substrate support assembly having the lift pin assembly, and a method of handling a substrate. The lift pin assembly includes a pin head detachably coupled with a pin body. The elongated pin body includes a first material, and the pin head includes a second material different from the first material. The second material is softer than the first material and may have a thermal conductivity about four (4) to eight (8) times of the first material. The second material has a melting point or a sublimation point of at least 600° C.

### CROSS-REFERENCE TO RELATED APPLICATIONS

This application claims benefit of U.S. Provisional Application Ser. No. 63/553,565, filed Feb. 14, 2024 (Attorney Docket No. APPM/44023469US01), of which is incorporated by reference in its entirety.

### BACKGROUND

### Field

The present disclosure relates to a lift pin assembly for a susceptor of a processing chamber, and, more specifically, relates to a lift pin assembly having a pin head configured to reduce scratching a substrate.

### Description of the Related Art

When a substrate, such as a silicon or a silicon carbide substrate, is processed in a processing chamber, a susceptor is used to support that substrate during processing. To load and unload the substrate from the susceptor, one or more lift pins are used to lift the substrate from or lower the substrate to the surface of the susceptor. Lift pin holes are provided in the susceptor to allow the lift pins to pass through.

During the processing of a substrate, the lift pin holes can involuntarily function as a heat sink due to convection. As a result, the lift pin holes dissipate heat at a faster rate than other area of the susceptor and has a lower temperature. The substrate area above the lift pin holes may also have a lower temperature than other areas, which causes the material deposited adjacent to the lift pin holes to be thinner than other areas. In addition, the lift pins, upon contact with the substrate, can scratch the backside of the substrate, which may affect subsequent processes of the substrate.

Thus, a need exists for an improved lift pin for processing a substrate.

### SUMMARY

Disclosed herein are a lift pin assembly, a substrate support assembly including a lift pin assembly, and a method for handling a substrate. The lift pin assembly includes a pin head detachably coupled with a pin body. The elongated pin body includes a first material, and the pin head includes a second material different from the first material. The second material is softer than the first material and may have a thermal conductivity about four (4) to eight (8) times of the first material. The first material and the second material are capable of surviving a temperature range between 400° C. and 1200° C. In an example, the first material and the second material have a melting point or a sublimation point of at least 600° C. The second material may have a melting point or a sublimation point of at least 1200° C.

The substrate support assembly includes a susceptor having one or more pin holes. A lift pin assembly is disposed inside the one or more pin holes. The lift pin assembly is configured according to various embodiments of the present disclosure.

The method of handling a substrate in a processing chamber includes disposing a substrate on a surface of a susceptor, raising up a pin head by a pin body, raising up the substrate by the pin head, removing the substrate from the susceptor, and lowering the pin body and the pin head inside a pin hole of a susceptor. The pin body includes a first material, and the pin head includes a second material different from the first material. The second material is softer than the first material and may have a thermal conductivity about four (4) to eight (8) times of the first material. The first material and the second material are capable of surviving a temperature range between 400° C. and 1200° C. In an example, the first material and the second material have a melting point or a sublimation point of at least 600° C. The second material may have a melting point or a sublimation point of at least 1200° C.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present disclosure.

FIG. 2 illustrates a schematic cross-sectional view of an EPI

processing chamber, according to an embodiment of the present disclosure.

FIG. 3 illustrates a schematic perspective view of a substrate support

assembly, according to an embodiment of the present disclosure.

FIG. 4a illustrates a schematic cross-sectional view of a susceptor having a pin hole, according to an embodiment of the present disclosure.

FIG. 4b illustrates a schematic cross-sectional view of a pin hole with a lift pin assembly, according to an embodiment of the present disclosure.

FIG. 5 illustrates a schematic cross-sectional view of a lift pin assembly, according to an embodiment of the present disclosure.

FIG. 6 illustrates a method for handling a substrate, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein is a lift pin assembly that includes a pin head detachably coupled with a pin body. In an embodiment, the pin head and the pin body are made of different materials. For example, the detachable pin head is made of a material configured to reduce scratching a substrate. The material of the pin head may include glassy carbon, graphite, or any other suitable materials. The detachable pin head may be replaced at a higher frequency than the pin body. The pin body is configured to support the pin head. The pin body may be made of a harder material, such as quartz, silicon carbide, or any other suitable materials. In an example, the material of the pin body may be the same or harder than the susceptor to avoid generating debris when the pin body moves inside the lift pin holes. The pin body functions as a sheath that protects the pin head from being scratched by the susceptor. The pin head is also configured to mitigate the heat sink effect. The conductivity of the pin head may be selected to be no greater than 10 times of the conductivity of the pin body.

In other embodiments, a top surface of the pin head may be further configured to reduce the chance of scratching a substrate. In an example, a center area of the top surface is configured to be higher than peripheral areas to reduce the size of a contact area between the pin head and the substrate. The pin head may include a leg inserted into a channel formed in the pin body. The leg is configured to have a predetermined heat capacity for mitigating the heat sink effect surrounding the lift pin holes. The lift pin includes a bulbous section configured to contact with the surfaces of the lift pin holes. The bulbous section can seal the lift pin holes, further reducing the heat sink effect. The lift pin assembly as set forth in the present disclosure can reduce scratching a substrate and increase the uniformity of deposited layers adjacent to the lift pin holes.

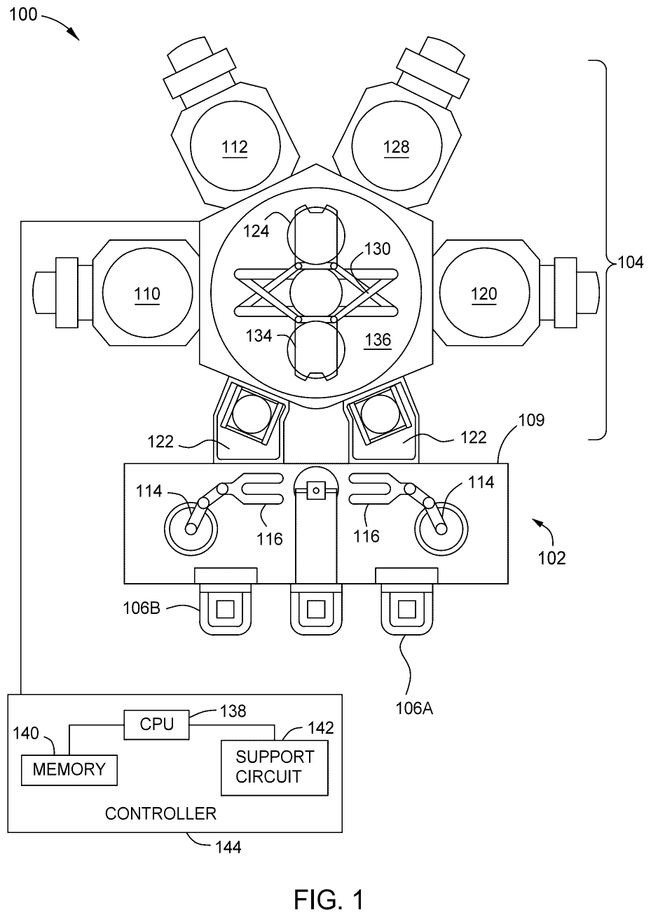

FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 is based on a CENTURA® integrated processing system, from Applied Materials, Inc., located in Santa Clara, California. It is contemplated that other processing systems (including those from other manufacturers) may be adapted to benefit from the disclosure. In one or more embodiments, the processing system includes a processing chamber having a lift pin assembly as set forth in the present disclosure.

The platform 104 includes a plurality of processing chambers 110, 112, 120, 128, and the one or more load lock chambers 122 that are coupled to a transfer chamber 136. The plurality of processing chambers 110, 112, 120, 128 may include an EPI chamber, a rapid thermal process chamber, an etch chamber, and any other suitable chambers. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122.

In one or more embodiments, the factory interface 102 includes at least one docking station 109 and at least one factory interface robot 114 to facilitate the transfer of substrates. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, 128.

The controller 144 is coupled to the processing system 100 and is used to control processes and methods, such as the operations of the methods described herein (for example the operations of the method 1000 and/or the method 1050 described below). The controller 144 includes a central processing unit (CPU) 138, a memory 140 containing instructions, and support circuits 142 for the CPU. The controller 144 controls various items directly, or via other computers and/or controllers.

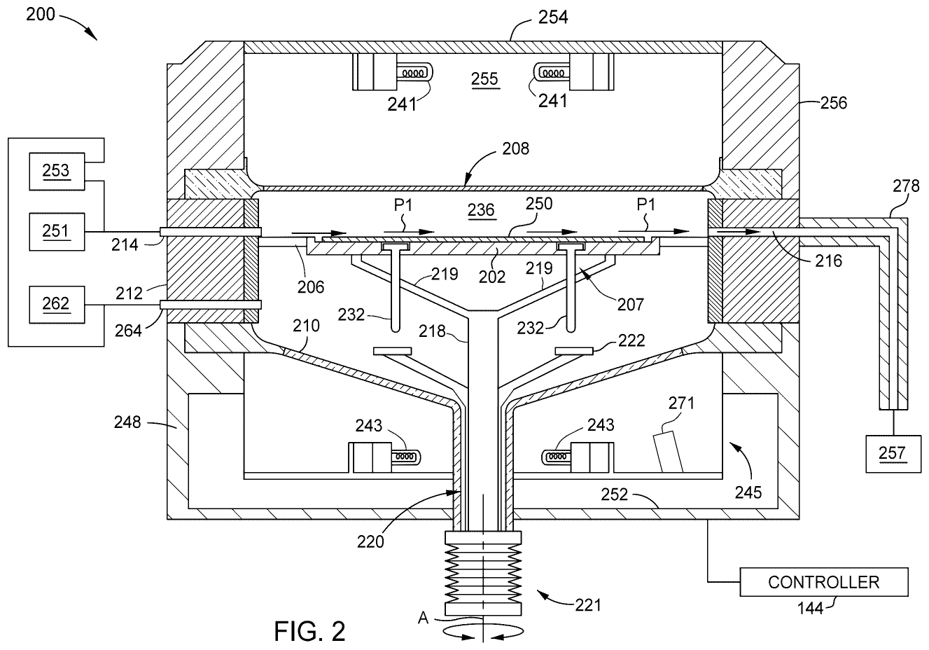

FIG. 2 illustrates a schematic cross-sectional view of an EPI processing chamber 200 according to an embodiment. The EPI processing chamber 200 is a deposition chamber to grow an EPI layer on a substrate 202 and includes one or more lift pin assemblies 232 as set forth in the present disclosure. The EPI chamber may be operated at elevated temperatures, such as between 400° C. and 1600° C. or between 600° C. and 1200° C. The elevated temperatures are maintained to process a variety of semiconductor substrates. Common polymeric materials used in components for handling substrates at lower temperature ranges may not survive these elevated temperatures. The lift pin assembly comprises a plurality of materials, which have a melting point or sublimation point of at least 600° C. or at least 1200° C. such that the lift pin assembly can survive the elevated operating temperatures. The processing chamber 200 can be used as one or more of the processing chambers 110, 112, 128 shown in FIG. 1.

The processing chamber 200 includes an upper body 256, a lower body 248 disposed below the upper body 256, and a flow module 212 disposed between the upper body 256 and the lower body 248. The upper body 256, the flow module 212, and the lower body 248 form a chamber body. Disposed within the chamber body is a substrate support assembly 206, an upper window 208 (such as an upper dome), a lower window 210 (such as a lower dome), a plurality of upper heat sources 241, and a plurality of lower heat sources 243. As shown, the controller 144 is in communication with the processing chamber 200 and is used to control processes and methods of at least the processing chamber 200.

The plurality of upper heat sources 241 are disposed between the upper window 208 and a lid 254. The plurality of upper heat sources 241 form a portion of the upper heating module 255. The plurality of lower heat sources 243 are disposed between the lower window 210 and a chamber floor 252. The plurality of lower heat sources 243 form a portion of a lower heating module 245. The upper window 208 is an upper dome and is formed at least partially of an energy transmissive material, such as quartz. The lower window 210 is a lower dome and is formed at least partially of an energy transmissive material, such as quartz.

According to an embodiment, the heat sources 241, 243 are lamps that are capable of generating infrared radiation. Other heat sources that are capable of generating infrared radiation are contemplated, such as resistive heaters, light emitting diodes (LEDs), and/or lasers.

The processing chamber 200 includes one or more thermal sensors 271 configured to detect a thermal condition of the processing chamber 200. The one or more thermal sensors 271 may include one or more cameras, one or more pyrometers, one or more thermoelectric sensors, and/or one or more thermal labels. The one or more thermal sensors 271 can be mounted, for example, below the lower window 210 (as shown in FIG. 2), or above the upper window 208 (such as on or in the lid 254), or any other suitable place in the processing chamber 200. In one example, a pyrometer is mounted above the upper window 208 and is configured to remotely measure temperature of the substrate 202 and the substrate support assembly 206 during the growth process of an EPI layer.

The substrate support assembly 206 is disposed between the upper window 208 and the lower window 210. The substrate support assembly 206 supports the substrate 202 and has a plurality of pin holes 207. The substrate support assembly 206 is supported by an inner shaft 218 coupled with a motion assembly 221. The motion assembly 221 includes one or more actuators and/or adjustment devices that provide movement and/or adjustment for the inner shaft 218, which, in turn, moves the substrate support assembly 206 and the substrate 202. The substrate support assembly 206 is coupled to the inner shaft 218 through one or more arms 219. The lift pin holes 207 of the substrate support assembly 206 are each sized to accommodate a lift pin assembly 232 that is used to lift the substrate 202 from the substrate support assembly 206 or lower the same to the substrate support assembly 206. The lift pin assembly 232 is coupled with the actuator 221 via an outer shaft 220. The outer shaft 220 includes a plurality of pedestals 222 configured to support the lift pin assembly 232. According to an embodiment, the lift pin assembly 232 includes a pin head detachably coupled with a lift body. Details of the lift pin assembly 232 will be described in other sections of the present disclosure.

The flow module 212 includes a plurality of gas inlets 214, a plurality of purge gas inlets 264, and one or more gas exhaust outlets 216. The gas inlets 214 are connected with a plurality of process gas sources 251, 253 and provides a cross-flow of precursors across a top surface 250 of the substrate 202. The purge gas inlets 264 are connected to a purge gas source 262 and provide purge gas to the EPI chamber 200. The plurality of gas inlets 214 and the plurality of purge gas inlets 264 are disposed on the opposite side of the flow module 212 from the one or more gas exhaust outlets 216. The one or more gas exhaust outlets 216 are connected to or include an exhaust system 278. The exhaust system 278 fluidly connects the one or more gas exhaust outlets 216 and the exhaust pump 257. The exhaust system 278 is disposed on an opposite side of the processing chamber 200 relative to the flow module 212.

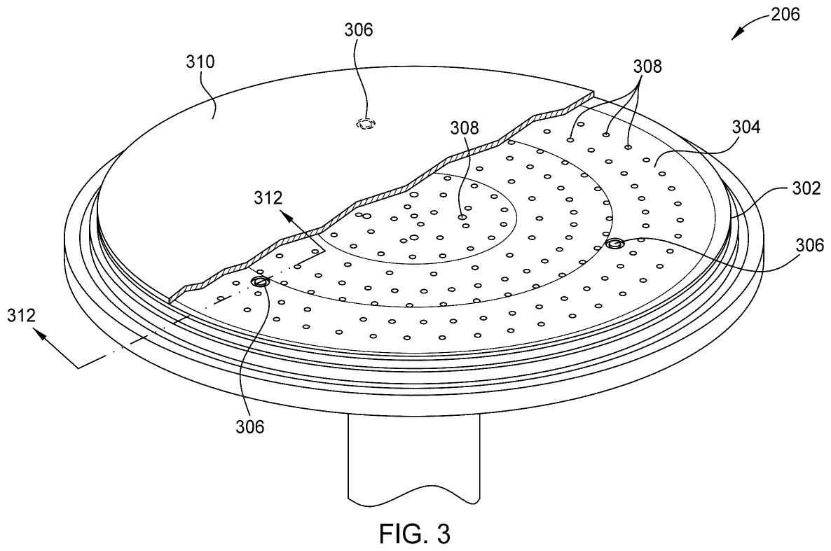

FIG. 3 illustrates a schematic perspective view of a substrate support assembly 206, according to an embodiment of the present disclosure. The substrate support assembly 206 includes a susceptor 302 supporting a substrate 310. The susceptor 302 includes a top surface 304 having one or more pin holes 306, such as three pin holes 306 shown in FIG. 3. The susceptor 302 is not limited to have three pin holes and may have any suitable number of pin holes, such as four, five, or even a greater number of pin holes. In some embodiments, one or more through holes 308 may be provided through the susceptor 302 to facilitate providing a backside gas to the backside region of the substrate or providing a vacuum to retain the substrate 310 on the substrate support. The susceptor 302 may be made of any suitable materials that have adequate chemical resistance to the chemistry in the processing chamber. The material of the susceptor 302 may include aluminum, alumina, quartz, silicon carbide, graphite, stainless steel, or any other suitable materials.

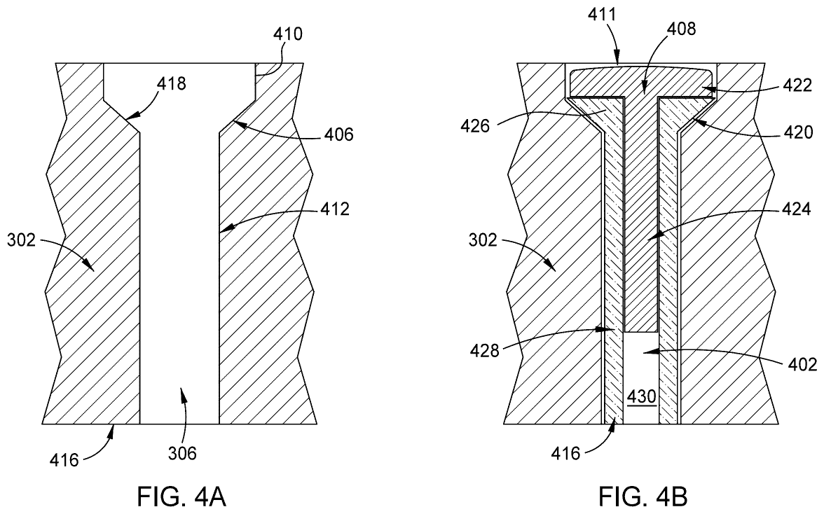

FIG. 4a illustrates a schematic cross-sectional view of the pin hole pin hole 306 along the lines 312 of FIG. 3 without a lift pin assembly, according to an embodiment. The susceptor 302 includes the lift pin hole 306. The lift pin hole 306 functions as a through hole that extends through the thickness of the susceptor 302, such as from a top surface 304 to a bottom surface 416 of the susceptor 302. According to an embodiment, the lift pin hole 306 is funnel shaped to support a lift pin assembly disposed inside the lift pin hole 306. For example, the lift pin hole 306 includes a first cylindrical portion 410, a second cylindrical portion 412, and a transition portion 406 connecting the first cylindrical portion 410 and the second cylindrical portion 412. The first cylindrical portion 410 is shallow and disposed adjacent to the surface 304. The second cylindrical portion 412 is long and extends through the susceptor 302. The first cylindrical portion 410 has a larger diameter than the second cylindrical portion 412. The transition portion 406 forms a connection between the first cylindrical portion 410 and the second cylindrical portion 412. In an embodiment, the transition portion 406 has a frustum shape having an upward facing surface 418 configured to support a lift pin assembly resting in the lift pin hole 306.

FIG. 4b illustrates a schematic cross-sectional view of the susceptor 302 with a lift pin assembly 402 resting in the lift pin hole 306, according to an embodiment. The lift pin assembly 402 has a shape that generally conforms with the shape of the lift pin hole 306. For example, the lift pin assembly 402 is generally funnel-shaped. The lift pin assembly 402 has a downward facing surface 420 configured to contact the upward facing surface 418 of the lift pin hole 306, thus sealing the lift pin hole 306 and reducing heat loss by convection. In an embodiment, the lift pin assembly 402 includes a pin head 408 detachably coupled with an elongated pin body 414. The pin head 408 is supported by the pin body 414 and can be lifted up or lowered down by the pin body 414. FIG. 4b shows a resting position of the lift pin assembly 402, in which position the pin head 408 is substantially disposed inside the lift pin hole 306. As a result, the top surface 411 of the pin head 408 is below the surface 304 of the susceptor 302. In an embodiment, the top surface 411 of the pin head 408 is about 0.5 mm, or 1.0 mm below the surface 304 of the susceptor 302.

The pin head 408 is configured to reduce substrate scratching and heat-sink effect. A material for the pin head 408 may be selected to be softer than the pin body 414 and the substrate. The material for the pin head 408 may also have a thermal conductivity a few times higher than that of the pin body. In an embodiment, the thermal conductivity of the material for the pin head may be no greater than 10 times of the pin body or about four (4) to eight (8) times of the pin body When a pin head has a much higher conductivity than the pin body, it can cause large temperature variations across the pin hole area. In an embodiment, the material for the pin head 408 may include glassy carbon, graphite, or any other suitable materials. The pin head 408 may be made of the material or have the material deposited as a thin layer on the top surface 411.

In an example, the pin head 408 includes a cap 422 and a leg 424. The cap 422 is disposed substantially within the first cylindrical portion 410. The cap 422 may have a cylindrical shape whose diameter is slightly shorter than that of the first cylindrical portion 410. The leg 424 extends into the pin body 414. When the pin body 414 includes a through channel 430, the leg 424 has a length configured to have sufficient heat capacity to mitigate the heat sink effect. In an example, the length of the leg 424 may be about half the thickness of the susceptor 302.

The pin body 414 may have a bulbous portion 426 supported by a cylindrical portion 428. The bulbous portion 426 is disposed at an upper end of the pin body 414 and supports the cap 422 of the pin head 408. The bulbous portion 426 is configured to have a similar shape with the connecting portion 406. The downward facing surface 420 is disposed on the bulbous portion 426 and contacts with the upward facing surface 418 to seal the lift pin hole 306 when the lift pin assembly 402 is at a resting position, thus reducing heat loss by convection. The cylindrical portion 428 of the pin body 414 extends through the susceptor 302 and is configured to couple with a lift pedestal 222 (shown in FIG. 2) below the susceptor 302. Thus, the cylindrical portion 428 of the pin body 414 is longer than the thickness of the susceptor 302. The cylindrical portion 428 includes a channel 430, which may be a blind channel or a through channel.

The pin head 408 is detachably coupled with the pin body 414. Any suitable mechanisms may be used to couple the pin head 408 to the pin body 414, including threads, fitting, and sleeves.

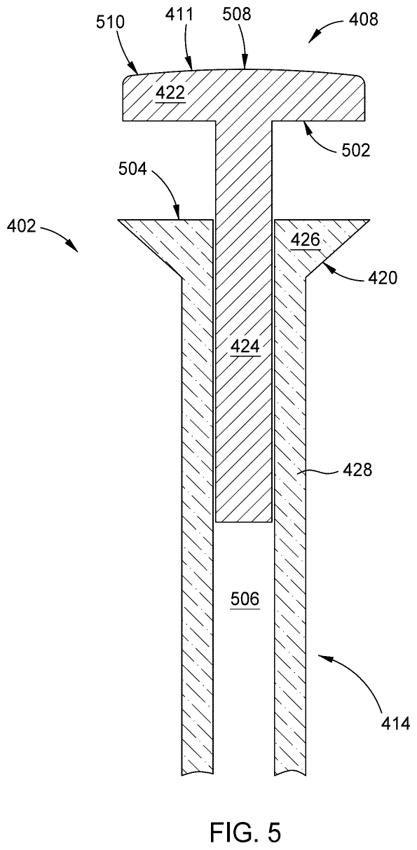

FIG. 5 illustrates a schematic cross-sectional view of a lift pin assembly 402, according to an embodiment. The lift pin assembly 402 includes the pin head 408 and the pin body 414. The pin head 408 includes a top surface 411, in which a center portion 508 is higher than a peripheral portion 510. When the pin assembly 402 lifts up a substrate, the center portion 508 is configured to contact the substrate while the peripheral portion 510 does not contact the substrate because the peripheral portion 510 is lower than the center portion 508. The reduced contact area with the substrate also reduces the chances to scratch the substrate. The pin head 408 has a cap 422 which has a bottom surface 502 that is configured to contact with a top surface 504 of the pin body 414. The pin head 408 also has a leg 424 coupled with the cap 422. The leg has a smaller diameter than that of the cap 422. The leg 424 can be inserted into a channel 506 formed inside the pin body 414. The channel 506 may extend through the entire pin body 414 (a through channel) or only a partial portion of the pin body 414 (a blind channel).

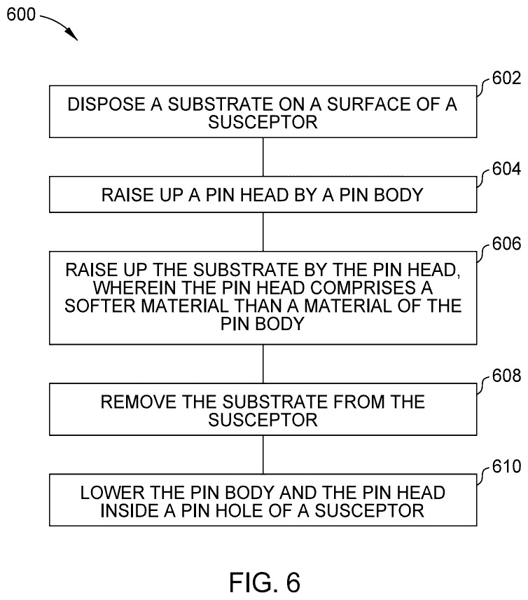

FIG. 6 illustrates a method 600 for handling a substrate in a processing chamber, according to an embodiment. At operation 602, a substrate is disposed on the surface of a susceptor. The susceptor includes a plurality of pin holes, each of which contains a lift pin assembly. At operation 604, the lift pin assembly is raised up by an actuator. The lift pin assembly includes a pin body and a pin head. The actuator is configured to lift the pin body, which, in turn, raises up the pin head. At operation 606, the pin head contacts the substrate disposed on the surface of the susceptor and raises up the substrate. To reduce scratching, the pin head comprises a softer material than the pin body. At operation 608, the substrate is removed from the pin head by a robotic arm. At operation 610, the lift pin assembly is lowered to the inside of the lift pin hole.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A lift pin assembly for a substrate support assembly, comprising:
an elongated pin body comprising a first material; and
a pin head detachably coupled with the elongated pin body and comprising a second material different from the first material, wherein the second material is softer than the first material, and the second material has a melting point or a sublimation point of at least 600° C.

2. The lift pin assembly of claim 1, wherein the second material has a melting point or a sublimation point of at least 1200° C.

3. The lift pin assembly of claim 2, wherein the second material of the pin head has a thermal conductivity of about four (4) to eight (8) times of the first material of the pin body.

4. The lift pin assembly of claim 1, wherein the pin head comprises a cap coupled with a leg, and a bottom surface of the cap is supported by a top surface of the pin body.

5. The lift pin assembly of claim 4, wherein the leg is disposed inside a channel of the elongated pin body.

6. The lift pin assembly of claim 5, wherein the cap comprises glassy carbon.

7. The lift pin assembly of claim 6, wherein a length of the leg is about half of a thickness of a susceptor of the substrate support assembly.

8. The lift pin assembly of claim 4, wherein the pin head comprises a top surface that is uneven.

9. The lift pin assembly of claim 8, wherein the top surface comprises a layer of glassy carbon, and the leg comprises quartz.

10. The lift pin assembly of claim 1, wherein the elongated pin body comprises a bulbous portion disposed at an upper end and a cylindrical portion below the bulbous portion.

11. The lift pin assembly of claim 10, wherein the elongated pin body comprises a channel that extends through the bulbous portion.

12. The lift pin assembly of claim 11, wherein the first material is selected from quartz, aluminum, silicon carbide, or stainless steel.

13. A substrate support assembly for an epitaxy chamber, comprising:
a susceptor comprising a lift pin hole; and
a lift pin assembly disposed within the lift pin hole and comprising:
an elongated body comprising a first material; and
a pin head detachably coupled with the elongated body and comprising a second material different from the second material,
wherein the second material is softer than the first material, and the second material has a melting point or a sublimation point of at least 600° C.

14. The substrate support assembly of claim 13, wherein the lift pin hole has a funnel shape comprising a frustum portion connecting a first cylindrical portion and a second cylindrical portion.

15. The substrate support assembly of claim 14, wherein the lift pin assembly generally conforms to the funnel shape of the lift pin hole.

16. The substrate support assembly of claim 15, wherein the lift pin assembly includes a downward facing surface configured to contact with an upward facing surface of the frustum portion of the lift pin hole.

17. The substrate support assembly of claim 16, wherein the first material is harder than the second material of the susceptor, and the second material has a thermal conductivity of about four (4) to eight (8) times of the first material.

18. The substrate support assembly of claim 13, wherein the pin head comprises a top surface disposed below a top surface of the susceptor.

19. The substrate support assembly of claim 18, wherein the pin head comprises glassy carbon.

20. A method of handling a substrate in a processing chamber, comprising:
raising up a pin head by a pin body, the pin body disposed in a lift pin hole formed through a susceptor;
raising a substrate by the pin head, wherein the pin body comprises a first material different from a second material comprised by the pin head, wherein the second material is softer than the first material and the second material has a melting point or a sublimation point of at least 600° C.; and
removing the substrate from the susceptor.
